(19) United States
(12) Patent Application Publication
(10) Pub. No.: US 2006/0191871 A1
(43) Pub. Date: Aug. 31, 2006

(54) CMP SLURRY DELIVERY SYSTEM AND METHOD OF MIXING SLURRY THEREOF

(76) Inventors: Sheng-Yu Chen, Tai-Chung Hsien (TW); Te-Sung Hung, Hsin-Chu City (TW); Chi-Piao Cheng, Taipei City (TW); Chung-Jung Cheng, Hsin-Chu Hsien (TW); Kaung-Wu Nieh, Tai-Chung City (TW); Po-Yuan Cheng, Hsin-Chu City (TW); Jiann-Fu Chen, Hsin-Chu City (TW); Chun-Ting Hu, Hsin-Chu City (TW); Tzu-Yu Tseng, Kao-Hsiung City (TW); Tzu-Yi Hsieh, Hsin-Chu City (TW); Hung-Chi Pai, Nan-Tou City (TW); Yung-Chieh Kuo, Hsin-Chu Hsien (TW)

Correspondence Address: NORTH AMERICA INTELLECTUAL PROPERTY CORPORATION, P.O. BOX 506, MERRIFIELD, VA, 22116, US

(21) Appl. No.: 10/906,584

(22) Filed: Feb. 25, 2005

(51) Int. Cl. H01L 21/306; C23F 1/00; B44C 1/22; C03C 15/00

(52) U.S. Cl. 216/89; 156/345.12

(57) ABSTRACT

A CMP slurry delivery system includes a delivery pipe, a first slurry supply reservoir coupled to the delivery pipe for supplying an abrasive, a second slurry supply reservoir coupled to the delivery pipe for supplying a clean chemical, a third slurry supply reservoir coupled to the delivery pipe for supplying a corrosion inhibitor, and a fourth slurry supply reservoir for supplying an oxidizer.

### BACKGROUND OF INVENTION

1. Field of the Invention

The present invention relates to a CMP slurry delivery system and method of mixing slurry thereof, and more particularly, to a CMP slurry delivery system and a method of mixing slurry capable of preventing slurry residue and corrosion.

2. Description of the Prior Art

The chemical mechanical polishing (CMP) process is one of the most common and the most essential planarization processes to date. The CMP process aims to topographically planarize a thin film disposed on a wafer surface so as to ensure the wafer has a smooth surface. For fabrication of damascene metal connection wires, such as copper conduction wires, the CMP process is an irreplaceable process.

In the course of a CMP process, the thin film is removed chemically and mechanically, and thus many process parameters, such as characteristics of the thin film, the composition, pH value, and mixing method of the slurry, the material of the polishing pad, the rotation speed of the platen, etc., have to be taken into consideration. Among all the process parameters, the composition, pH value, and mixing method of the slurry are essential to the yield of the CMP process. The slurry substantially includes an abrasive and an oxidizer, and the slurry becomes a viscous fluid after the abrasive and the oxidizer are mixed. In addition, the pH value also influences the rate of the CMP process. Normally, the smaller the pH value is, the more powerful the chemical polishing effect is. Therefore, the viscosity of the slurry makes it easy to generate slurry residues in the CMP slurry delivery system. Besides, the acidity and corrosiveness of the slurry tend to damage the CMP slurry delivery system and the wafer.

Please refer to FIG. 1, which is a schematic diagram illustrating a conventional CMP slurry delivery system 10 for use in a CMP apparatus. As shown in FIG. 1, the conventional CMP slurry delivery system 10 includes a mixer 12, a first slurry supply reservoir 14, a second slurry supply reservoir 16, and a DI water purger 18. The first slurry supply reservoir 14, the second slurry supply reservoir 16, and the DI water purger 18 are used to respectively provide the mixer 12 with the abrasive, the oxidizer, and DI water. In the course of the CMP process, the first slurry supply reservoir 14 and the second slurry supply reservoir 16, which communicate with the mixer 12, implant the abrasive and the oxidizer into the mixer 12. The abrasive and the oxidizer are therefore mixed in the mixer 12 forming the slurry, and are delivered to a polishing device 20 of the CMP apparatus. After the CMP process is carried out, the DI water purger 18 implants DI water into the mixer 12 to rinse mixer 12.

Since the slurry is highly corrosive and viscous, the slurry tends to remains in the mixer 12 and the delivery pipe. Consequently, the CMP slurry delivery system 10 is easily damaged. In addition, the slurry residues may cause micro-scratches on the wafer surface, and the corrosiveness of the slurry may also corrode the CMP slurry delivery system 10 and the wafer.

### SUMMARY OF INVENTION

It is therefore a primary object of the claimed invention to provide a CMP slurry delivery system of a method of mixing slurry thereof to overcome the aforementioned problems.

According to a preferred embodiment of the present invention, a CMP slurry delivery system is disclosed. The CMP slurry delivery system includes a delivery pipe, a DI water purger, a first slurry supply reservoir, a second slurry supply reservoir, a third slurry supply reservoir, and a fourth slurry supply reservoir. The delivery pipe has a first end and a second end, and the first end communicates with a polishing device. The DI water purger communicates with the second end of the delivery pipe. The first slurry supply reservoir communicates with the delivery pipe at a position close to the second end for supplying an abrasive to the delivery pipe, and the first slurry supply reservoir has a check valve installed between the first slurry supply reservoir and the delivery pipe. The second slurry supply reservoir communicates with the delivery pipe at a position between the first slurry supply reservoir and the first end for supplying a clean chemical to the delivery pipe, and the second slurry supply reservoir has a check valve installed between the second slurry supply reservoir and the delivery pipe. The third slurry supply reservoir communicates with the delivery pipe at a position between the first slurry supply reservoir and the first end for supplying a corrosion inhibitor to the delivery pipe, and the third slurry supply reservoir has a check valve installed between the third slurry supply reservoir and the delivery pipe. The fourth slurry supply reservoir communicates with the delivery pipe at a position close to the first end for supplying an abrasive to the delivery pipe, and the fourth slurry supply reservoir has a check valve installed between the fourth slurry supply reservoir and the delivery pipe. The abrasive, the oxidizer, the clean chemical, and the corrosion inhibitor are rapidly mixed, and directly delivered to the polishing device.

In combination with the CMP slurry delivery system, the present invention also discloses a method of mixing slurry. The method of the present invention includes the following steps. First, a delivery pipe communicating with a polishing device of a chemical mechanical polishing apparatus at a first end is provided. The delivery pipe further includes a first inlet, a second inlet, a third inlet, and a fourth inlet. The first inlet is positioned far from the first end, the fourth inlet is positioned closer to the first end, and the second inlet and the third inlet are positioned between the first inlet and the fourth inlet. Subsequently, an abrasive, a clean chemical, a corrosion inhibitor, and an oxidizer are respectively implanted into the delivery pipe via the first inlet, the second inlet, the third inlet, and the fourth inlet. The first inlet, the second inlet, the third inlet, and the fourth inlet each include a check valve, and the abrasive, the clean chemical, the corrosion inhibitor, and the oxidizer are rapidly mixed in the delivery pipe and directly delivered to the polishing device.

The slurry supplied by the CMP slurry delivery system of the present not only includes the abrasive and the oxidizer, but also includes the clean chemical and the corrosion inhibitor. In addition, the abrasive, the oxidizer, the clean chemical, and the corrosion inhibitor are rapidly mixed in the delivery pipe, and directly delivered to the polishing device. As a result, the CMP slurry delivery system is able to prevent slurry residue and corrosion. Furthermore, each slurry supply reservoir (including the first slurry supply reservoir, the second slurry supply reservoir, the third slurry reservoir, and the fourth slurry reservoir) includes a check valve installed at less than 5% the distance from each slurry supply reservoir to the delivery pipe, thereby preventing contamination problems.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is a schematic diagram illustrating a conventional CMP slurry delivery system for use in a CMP apparatus.

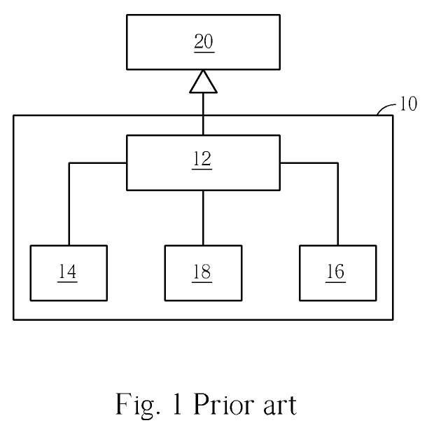

FIG. 2 is a schematic diagram illustrating a CMP slurry delivery system according to a preferred embodiment of the present invention.

FIG. 3 is a schematic diagram illustrating a method of mixing slurry according to the present invention.

### DETAILED DESCRIPTION

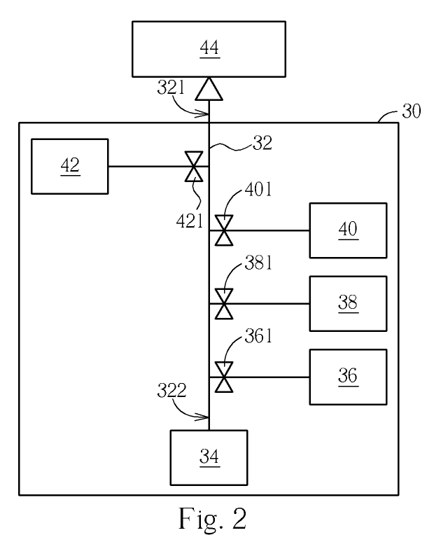

Please refer to FIG. 2, which is a schematic diagram illustrating a CMP slurry delivery system 30 according to a preferred embodiment of the present invention. As shown in FIG. 2, the CMP slurry delivery system 30 includes a delivery pipe 32, a DI water purger 34, a first slurry supply reservoir 36, a second slurry supply reservoir 38, a third slurry supply reservoir 40, and a fourth slurry supply reservoir 42. The first end 321 of the delivery pipe 32 communicates with a polishing device 44 of a CMP apparatus so as to deliver the slurry to the polishing device 44, and the second end 322 of the delivery pipe 32 communicates with the DI water purger 34 so that the DI water purger 34 can rinse the delivery pipe 22. The first slurry supply reservoir 36, the second slurry supply reservoir 38, the third slurry supply reservoir 40, and the fourth slurry supply reservoir 42 all communicate with the delivery pipe 32, and each slurry supply reservoir has a respective check valve 361, 381, 401, and 421 to prevent backflow of the slurry. Furthermore, the first slurry supply reservoir 36, the second slurry supply reservoir 38, the third slurry supply reservoir 40, and the fourth slurry supply reservoir 42 are respectively coupled to the delivery pipe 32 from the second end 322 to the first end 321 in order so as to implant different components of the slurry into the delivery pipe 32. In this embodiment, the first slurry supply reservoir 36 is used to provide the delivery pipe 32 with an abrasive, the second slurry supply reservoir 38 is used to provide the delivery pipe 32 with a clean chemical for cleaning the delivery pipe 32, the third slurry supply reservoir 40 is used to provide the delivery pipe 32 with a corrosion inhibitor to prevent corrosion, and the fourth slurry supply reservoir 42 is used to provide the delivery pipe 32 with an oxidizer. The check valves 361, 381, 401, and 421 are respectively installed at less than 5% the distance from the first slurry supply reservoir 36, the second slurry supply reservoir 38, the third slurry supply reservoir 40, and the fourth slurry supply reservoir 42 to the delivery pipe 32, thereby preventing contamination problems. In addition, the check valves 361, 381, 401, and 421 are selected from anti-corrosive material, such as stainless steel and perfluoroalkoxy (PFA), and PFA is preferable.

The abrasive is selected from alumina, silica, silica fume, cerium oxide, and zirconium oxide, or other compounds commonly used as an abrasive. The oxidizer is selected from hydrogen peroxide, ferric nitrate, potassium iodinate, etc. The clean chemical is selected from citric acid, oxalic acid, and other organic acids. The corrosion inhibitor is selected from benzotrazole (BTA), 2-mercapto-benzothiazole (MBT), benzimidazole (BIA), tolyltrizole (TTA), 5-hexyl-1,2,3-benzotriazole (C6BTA), 3-amino-5-heptyl-1,2,4-triazole (AHT), 2-amino-thiazole (AZT), 2-amino-4,6-dimethyl-parimidine (ADMP), 3-phenyl-1,2,4-triazole (PTH), 3-phenyl-1,2,4-triazole-5-one, piperidine, phenyl-amino-triazine-dithiol (PTD), potassium ethylxanthate (KEX), benzylamine (BZA), ethanolamine, sodium tripolyphosphate, etc.

The CMP slurry delivery system 30 is superior to the prior art since the slurry is rapidly mixed in the delivery pipe 32, and instantly delivered to the polishing device 44. Consequently, slurry residues are effectively reduced. In addition, because the oxidizer is mixed with the abrasive close to the first end 321 of the delivery pipe 32, the viscosity of the slurry in the CMP slurry delivery system 30 is lower than the viscosity of the slurry in the conventional CMP slurry delivery system. Furthermore, the risk of corrosion is greatly reduced by adding the corrosion inhibitor.

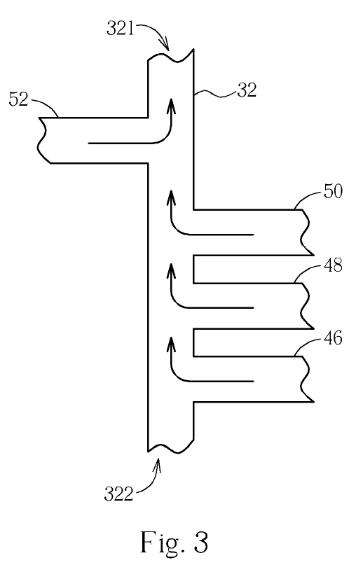

In combination with the CMP slurry delivery system 30, the present invention also provides a method of mixing slurry. Please refer to FIG. 3 along with FIG. 2. FIG. 3 is a schematic diagram illustrating the method of mixing slurry according to the present invention, where like components are denoted by like numerals in FIG. 2 and FIG. 3. As shown in FIG. 3, a delivery pipe 32 having a first end 321, which communicates with a polishing device 44 (not shown in FIG. 3), is provided. The second end 322 of the delivery pipe 32 is connected to a DI water purger 34 (not shown in FIG. 3). The abrasive is implanted into the delivery pipe 32 via a first inlet 46, the clean chemical is implanted into the delivery pipe 32 via a second inlet 48, the corrosion inhibitor is implanted into the delivery pipe 32 via a third inlet 50, and the oxidizer is implanted into the delivery pipe 32 via a fourth inlet 52. Accordingly, the abrasive, the clean chemical, the corrosion inhibitor, and the oxidizer are rapidly mixed and flow to the polishing device 44. It is noted that the compositions of the abrasive, the clean chemical, the corrosion inhibitor, and the oxidizer can be adjusted for achieving preferable CMP and cleaning effects. In addition, DI water is implanted into the delivery pipe 32 by the DI water purger 34 after the CMP process is finished or when necessary.

With the CMP slurry delivery system and the method of mixing slurry of the present invention, the problems of slurry residue and corrosion can be greatly reduced. It is also to be appreciated that the positions of implanting the abrasive, the clean chemical, the corrosion inhibitor, and the oxidizer can be adjusted. For example, the positions of implanting the clean chemical and the corrosion inhibitor can be exchanged. In addition, other reactants, such as a pH value buffer, surfactant, and chelating agent, can also be added into the delivery pipe 32 in the course of or after the CMP process for enhancing the CMP effect or the cleaning effect. In addition, the check valves are used to prevent the contamination of the CMP slurry delivery system.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A CMP slurry delivery system, comprising:
a delivery pipe comprising a first end and a second end, the first end communicating with a polishing device;
a DI water purger communicating with the second end of the delivery pipe;
a first slurry supply reservoir communicating with the delivery pipe at a position close to the second end for supplying an abrasive to the delivery pipe, the first slurry supply reservoir comprising a check valve installed between the first slurry supply reservoir and the delivery pipe;
a second slurry supply reservoir communicating with the delivery pipe at a position between the first slurry supply reservoir and the first end for supplying a clean chemical to the delivery pipe, the second slurry supply reservoir comprising a check valve installed between the second slurry supply reservoir and the delivery pipe;
a third slurry supply reservoir communicating with the delivery pipe at a position between the first slurry supply reservoir and the first end for supplying a corrosion inhibitor to the delivery pipe, the third slurry supply reservoir comprising a check valve installed between the third slurry supply reservoir and the delivery pipe; and
a fourth slurry supply reservoir communicating with the delivery pipe at a position close to the first end for supplying an oxidizer to the delivery pipe, the fourth slurry supply reservoir comprising a check valve installed between the fourth slurry supply reservoir and the delivery pipe;
wherein the abrasive, the oxidizer, the clean chemical, and the corrosion inhibitor are rapidly mixed, and directly delivered to the polishing device.

2. The CMP slurry delivery system of claim 1, wherein the second slurry supply reservoir communicates with the delivery pipe at a position between the first slurry supply reservoir and the third slurry supply reservoir.

3. The CMP slurry delivery system of claim 1, wherein the third slurry supply reservoir communicates with the delivery pipe at a position between the first slurry supply reservoir and the second slurry supply reservoir.

4. The CMP slurry delivery system of claim 1, wherein the abrasive is selected from a group consisting of alumina, silica, and silica fume.

5. The CMP slurry delivery system of claim 1, wherein the oxidizer is selected from a group consisting of hydrogen peroxide and ferric nitrate.

6. The CMP slurry delivery system of claim 1, wherein the clean chemical is selected from a group consisting of citric acid and oxalic acid.

7. The CMP slurry delivery system of claim 1, wherein the corrosion inhibitor is selected from a group consisting of benzotrazole (BTA), 2-mercapto-benzothiazole (MBT), benzimidazole (BIA), tolyltrizole (TTA), 5-hexyl-1,2,3-benzotriazole (C6BTA), 3-amino-5-heptyl-1,2,4-triazole (AHT), 2-amino-thiazole (AZT), 2-amino-4,6-dimethyl-parimidine (ADMP), 3-phenyl-1,2,4-triazole (PTH), 3-phenyl-1,2,4-triazole-5-one, piperidine, phenyl-amino-triazine-dithiol (PTD), potassium ethylxanthate (KEX), benzylamine (BZA), ethanolamine, and sodium tripolyphosphate.

8. A method of mixing slurry comprising:
providing a delivery pipe communicating with a polishing device of a chemical mechanical polishing apparatus at a first end, the delivery pipe further comprising a first inlet, a second inlet, a third inlet, and a fourth inlet, the first inlet being positioned far from the first end, the fourth inlet being positioned closer to the first end, the second inlet and the third inlet being positioned between the first inlet and the fourth inlet;
implanting an abrasive into the delivery pipe via the first inlet;
implanting a clean chemical into the delivery pipe via the second inlet;
implanting a corrosion inhibitor into the delivery pipe via the third inlet; and
implanting an oxidizer into the delivery pipe via the fourth inlet;
wherein the first inlet, the second inlet, the third inlet, and the fourth inlet each comprise a check valve; and the abrasive, the clean chemical, the corrosion inhibitor, and the oxidizer are rapidly mixed in the delivery pipe and directly delivered to the polishing device.

9. The method of claim 8, wherein the second inlet is positioned between the first inlet and the third inlet.

10. The method of claim 8, wherein the third inlet is positioned between the first inlet and the second inlet.

11. The method of claim 8, wherein the abrasive is selected from a group consisting of alumina, silica, and silica fume.

12. The method of claim 8, wherein the oxidizer is selected from a group consisting of hydrogen peroxide and ferric nitrate.

13. The method of claim 8, wherein the clean chemical is selected from a group consisting of citric acid and oxalic acid.

14. The method of claim 8, wherein the corrosion inhibitor is selected from a group consisting of benzotrazole (BTA), 2-mercapto-benzothiazole (MBT), benzimidazole (BIA), tolyltrizole (TTA), 5-hexyl-1,2,3-benzotriazole (C6BTA), 3-amino-5-heptyl-1,2,4-triazole (AHT), 2-amino-thiazole (AZT), 2-amino-4,6-dimethyl-parimidine (ADMP), 3-phenyl-1,2,4-triazole (PTH), 3-phenyl-1,2,4-triazole-5-one, piperidine, phenyl-amino-triazine-dithiol (PTD), potassium ethylxanthate (KEX), benzylamine (BZA), ethanolamine, and sodium tripolyphosphate.

15. The method of claim 8, further comprising a step of purging the delivery pipe with a DI water purger.

16. A CMP slurry delivery system, comprising:
a delivery pipe comprising a first end and a second end, the first end communicating with a polishing device;
a DI water purger communicating with the second end of the delivery pipe;
a plurality of slurry supply reservoirs communicating with the delivery pipe, each slurry supply reservoir comprising a check valve, and each check valve being positioned at less than 5% a distance from each slurry supply reservoir to the delivery pipe.

17. The CMP slurry delivery system of claim 16, wherein the plurality of slurry supply reservoirs are a first slurry supply reservoir for supplying an abrasive to the delivery pipe, a second slurry supply reservoir for supplying a clean chemical to the delivery pipe, a third slurry supply reservoir for supplying a corrosion inhibitor to the delivery pipe, and a fourth slurry reservoir for supplying an oxidizer to the delivery pipe.

18. The CMP slurry delivery system of claim 17, wherein the abrasive is selected from a group consisting of alumina, silica, and silica fume.

19. The CMP slurry delivery system of claim 17, wherein the oxidizer is selected from a group consisting of hydrogen peroxide and ferric nitrate.

20. The CMP slurry delivery system of claim 17, wherein the clean chemical is selected from a group consisting of citric acid and oxalic acid.

21. The CMP slurry delivery system of claim 17, wherein the corrosion inhibitor is selected from a group consisting of benzotrazole (BTA), 2-mercapto-benzothiazole (MBT), benzimidazole (BIA), tolyltrizole (TTA), 5-hexyl-1,2,3-benzotriazole (C6BTA), 3-amino-5-heptyl-1,2,4-triazole (AHT), 2-amino-thiazole (AZT), 2-amino-4,6-dimethyl-parimidine (ADMP), 3-phenyl-1,2,4-triazole (PTH), 3-phenyl-1,2,4-triazole-5-one, piperidine, phenyl-amino-triazine-dithiol (PTD), potassium ethylxanthate (KEX), benzylamine (BZA), ethanolamine, and sodium tripolyphosphate.

22. The CMP slurry delivery system of claim 17, wherein the first slurry supply reservoir communicates with the delivery pipe at a position close to the second end.

23. The CMP slurry delivery system of claim 17, wherein the second slurry supply reservoir communicates with the delivery pipe at a position between the first slurry supply reservoir and the first end.

24. The CMP slurry delivery system of claim 17, wherein the third slurry supply reservoir communicates with the delivery pipe at a position between the first slurry supply reservoir and the first end.

25. The CMP slurry delivery system of claim 17, wherein the fourth slurry supply reservoir communicates with the delivery pipe at a position close to the first end.

26. The CMP slurry delivery system of claim 17, wherein a material of each check valve is perfluoroalkoxy (PFA).
